(19) United States
(12) Patent Application Publication
(10) Pub. No.: US 2019/0052277 A1
(43) Pub. Date: Feb. 14, 2019

(54) FUNCTIONAL SAFETY CLOCKING FRAMEWORK FOR REAL TIME SYSTEMS

(71) Applicant: Intel Corporation, Santa Clara, CA (US)

(72) Inventors: JAGANNADHA RAO RAPETA, Folsom, CA (US); ASAD AZAM, Folsom, CA (US); AMIT KUMAR SRIVASTAVA, Folsom, CA (US); MIKAL HUNSAKER, El Dorado Hills, CA (US)

(73) Assignee: Intel Corporation, Santa Clara, CA (US)

(21) Appl. No.: 16/017,865

(22) Filed: Jun. 25, 2018

(51) Int. Cl. H03L 7/08; G05B 9/03; H03L 7/081

(52) U.S. Cl. CPC H03L 7/0807; H03K 5/1565; H03L 7/081; G05B 9/03

(57) ABSTRACT

Methods and apparatus relating to functional safety clocking framework for real time systems are described. In an embodiment, clock monitoring logic circuitry monitors a plurality of clock signals. Safety island logic circuitry receives an error status signal from the clock monitoring logic circuitry based at least in part on a determination of whether an error exists for at least one of the plurality of clock signals. Safety logic circuitry to receive an interrupt signal from the safety island logic circuitry in response to a determination that the error status signal indicates existence of an error for at least one of the plurality of clock signals. Other embodiments are also disclosed and claimed.

### FIELD

The present disclosure generally relates to the field of electronics. More particularly, an embodiment relates to functional safety clocking framework for real time systems.

### BACKGROUND

Functional safety is important for the real time complex systems such as IOT (Internet Of Things) applications, like automotive and industrial segments. All these applications may impose tight constraints on the system to perform safely and reliably under complex and noisy system environments across a product's life cycle.

Apart from that silicon process, another challenge is reliability or aging degradation which can limit a product's life cycle. Manufactures spend a significant amount of time on validating their systems to address potential risks and to fix silicon process issues. But, it is still difficult to cover all the boundary conditions in order to maintain the safety requirements as imposed by automotive and industrial applications.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a block diagram of a system for a functional safety clocking framework, according to an embodiment.

FIG. 2 shows a sample error log, according to an embodiment.

FIG. 3 illustrates a flow diagram of a method to monitor errors for a functional safety clocking framework, according to an embodiment.

FIG. 4 illustrates a graph indicating sample aging bounds, according to an embodiment.

FIGS. 5 and 7 illustrate circuit diagrams in accordance with some embodiments.

FIG. 6 illustrates a sample timing diagram, according to an embodiment.

FIGS. 8 and 9 illustrates block diagrams of embodiments of computing systems, which may be utilized in various embodiments discussed herein.

FIGS. 10 and 11 illustrate various components of processers in accordance with some embodiments.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware (such as logic circuitry or more generally circuitry or circuit), software, firmware, or some combination thereof.

Some embodiments relate to a functional safety clocking framework for real time systems. Clocking for any Integrated Circuit (IC) semiconductor device is the backbone for integrated solutions since signals are processed in accordance with the clocking. To this end, techniques discussed herein may address safety concerns by providing a functional safety clocking framework, which would address functional failures and also provide a robust solution to address silicon degradation.

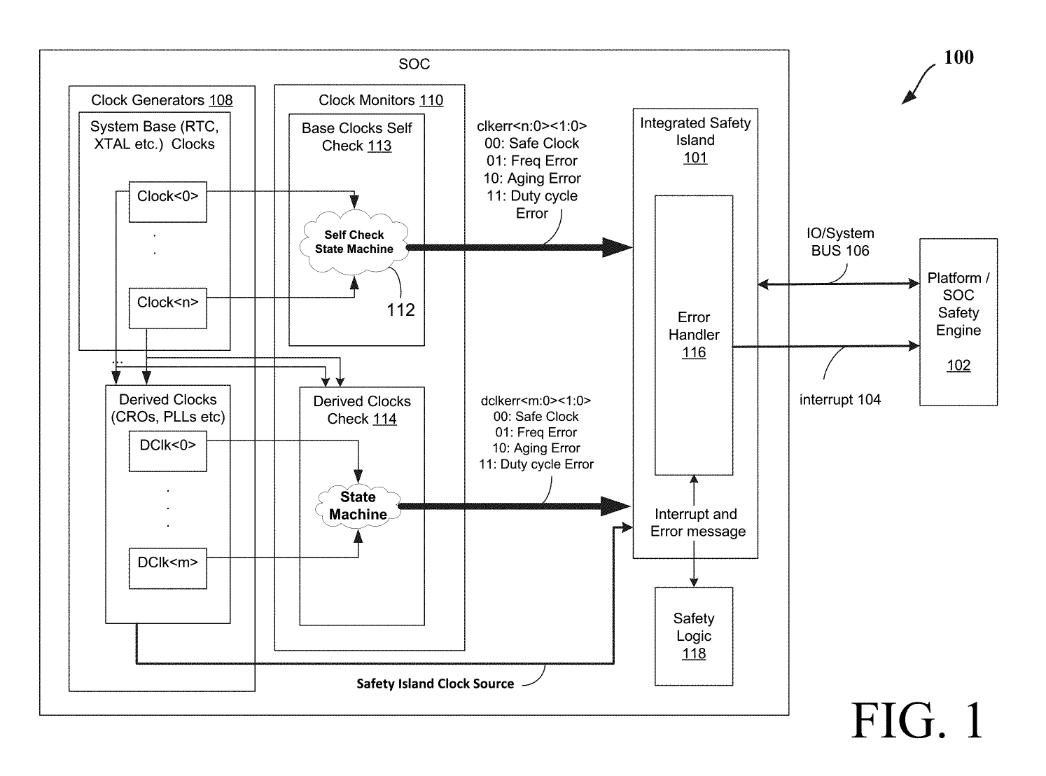

FIG. 1 illustrates a block diagram of a system 100 for a functional safety clocking framework, according to an embodiment. In an embodiment, safety island logic 101 is able to log error(s) and/or generate error reports. the safety island logic 101 may be integrated on-chip (or on a System On Chip (SOC or SoC)) or implemented off-chip with communication capability with components of the chip. In turn, the error log or error report can be used by application software (e.g., running on a processor) to configure the system under a recovery state (i.e., to recover from the error(s)) or park the system under safety state (e.g., to restrict some operations due to safety concerns) depending on the type of an error. The data for the error log or report may be stored in memory (such as any memory discussed herein with reference to other figures) for access by the software application. In an embodiment, the stored data may be readable and writable by the logic 101 and only readable by the application software. In this fashion, the stored data may only be modifiable by the logic 101 to avoid potential attacks that may change the error log through the software application.

In one or more embodiments, functional safety clocking framework engine (e.g., logic 102) has the capability to perform self-clock checking and/or clock cross-checking to monitor system fundamental clocks, Input/Output (I/O or IO), or other system clocks. The functional safety engine logic receives safety interrupt(s) 104 and performs classification operations based on severity of error(s). Depending upon severity, the safety engine 102 might take some autonomous or asynchronous actions to put the system in a safe state. The functional safety engine may also be responsible for relaying information to an end user, e.g., through Input/Output (I/O or IO)) subsystems (such as audio, visual, etc.). The functional clocking framework may also address silicon degradation issues by detecting reliability issues and informing the safety island 101 about degradation and log the error (e.g., via an IO or a system bus 106).

In an embodiment, system 100 is a self-sustained system which does not utilize any kind of platform level components, results in saving platform implementation costs and helps in terms of increasing higher unit selling price. Also, system 100 may provide a low cost SOC solution for various IOT/Real Time systems and meeting SOC safety requirements provided by safety guidelines (such as autonomous driving safety guidelines).

In one embodiment, logic and/or various components (including the SOC and/or engine 102) may be mounted or otherwise physically coupled to a vehicle. As discussed herein, a “vehicle” generally refers to any transportation device capable of being operated autonomously (with little or no human/driver intervention), such as an automobile, a truck, a motorcycle, an airplane, a helicopter, a vessel/ship, a train, a drone, etc. whether or not the vehicle is a passenger or commercial vehicle, and regardless of the power source type (such as one or more of: fossil fuel(s), solar energy, electric energy, chemical energy, nuclear energy, etc.) and regardless of the physical state of the power source (e.g., solid, liquid, gaseous, etc.) used to move the vehicle.

Furthermore, in various embodiments, SOC components run on RTC (Real Time clock), Calibrated/Clock Ring Oscillators (CRO), Crystal (XTAL) oscillators, and/or PLL (Phase-Locked Loop) clock generators 108. However, embodiments are not limited to these clock generator types and can also apply to other clock source generators, such as relaxation oscillators, MEMs (Micro Electro-Mechanical System) oscillators, etc.

Referring to FIG. 1, system 100 includes clock generators 108 (e.g., generating both base clocks as discussed above as well as derived clocks). Clock monitoring logic 110 can perform clock checks for both base and derived clocks as shown. In an example, the based clocks are generated (e.g., RTC, XTALs, etc.) and in turn the base clocks are used to generate the derived clocks.

For the base clocks, clock monitoring state machine 112 (which is part of the base clock self-checking logic 113) compares clock signals within the base clock domain with each other (for example, monitoring/comparing RTC vs. XTAL and/or XTAL vs RTC, and so on) and report the error log to Integrated Safety Island (ISI) logic 101. Derived clock monitoring logic 114 may utilize its own state machine to generate reports for derived clocks (DClk) based on reference base clocks. The base and derived clock check logic may then report clock errors like frequency, aging, clock lock, phase error, duty cycle, etc. to the safety island logic 101. A sample two-bit reporting code scheme is shown in FIG. 1, but other schemes/encoding (e.g., with more bits) may be used depending on the implementation.

In one embodiment, the safety island logic 101 is responsible for collecting logs of error in safety island clock domain(s) and as well as in other asynchronous domain(s) (e.g., in case of failure of clocks in the safety island clock domain(s)) to the system platform engine 102. Safety island error handler logic 116 categorizes errors depending on severity and/or fatality of errors and generates interrupt(s) 104. Logic 116 may also generate error messages. The interrupt information may be shared with logic 102 as indicated before as well as safety (e.g., firmware (FW)) logic 118 (which would provide local logic in case there is no connection to the safety engine 102). The error messages may also be communicated to the engine 102 through IO BUS/System Bus 106. In an embodiment, for lower severity cases where system software is available, the illustrated two-bit indicators may be used to configure system under recovery state.

In one embodiment, the following parameters may be used to indicate whether a component (e.g., SOC discussed with reference to FIG. 1) would qualify for the functional safety clocking framework:
Safe Clock: an indication to the safety island logic 101 whether a clock is running or not;
Clock Tolerance Limits: an indication of whether a clock is within frequency tolerance limits and under the limit of targeted bounded ppm (parts per million or how many errors per million) or error; and
Reliability Degradation: an indication quantifying the aging degradation of clock(s) to be monitored (e.g., checked for frequency distortion, duty cycle distortion, etc.).

However, embodiments discussed herein are not limited to clocking only and may be used to monitor and generate interrupts/logic to other features such as power droop, etc.

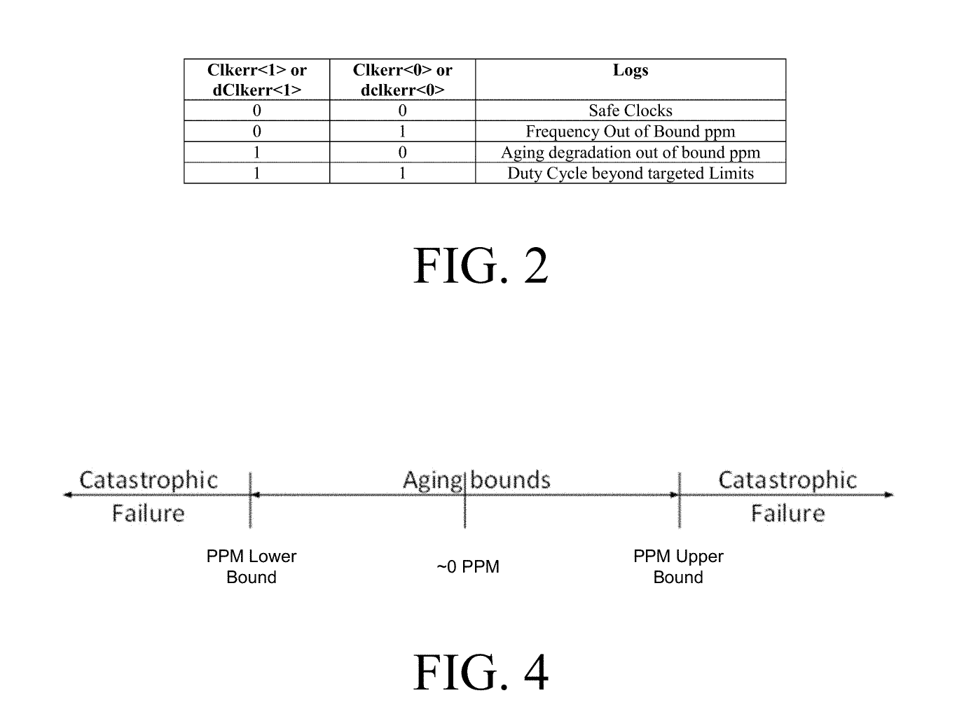

FIG. 2 shows a sample error log, according to an embodiment. The error log shown in FIG. 2 can be generated by the safety island logic 101 of FIG. 1 based on errors highlighted by clock monitoring logic 110 of FIG. 1 for the system base clock (Clkerr<1:0>) and for derived clocks (dclockerr<1:0>).

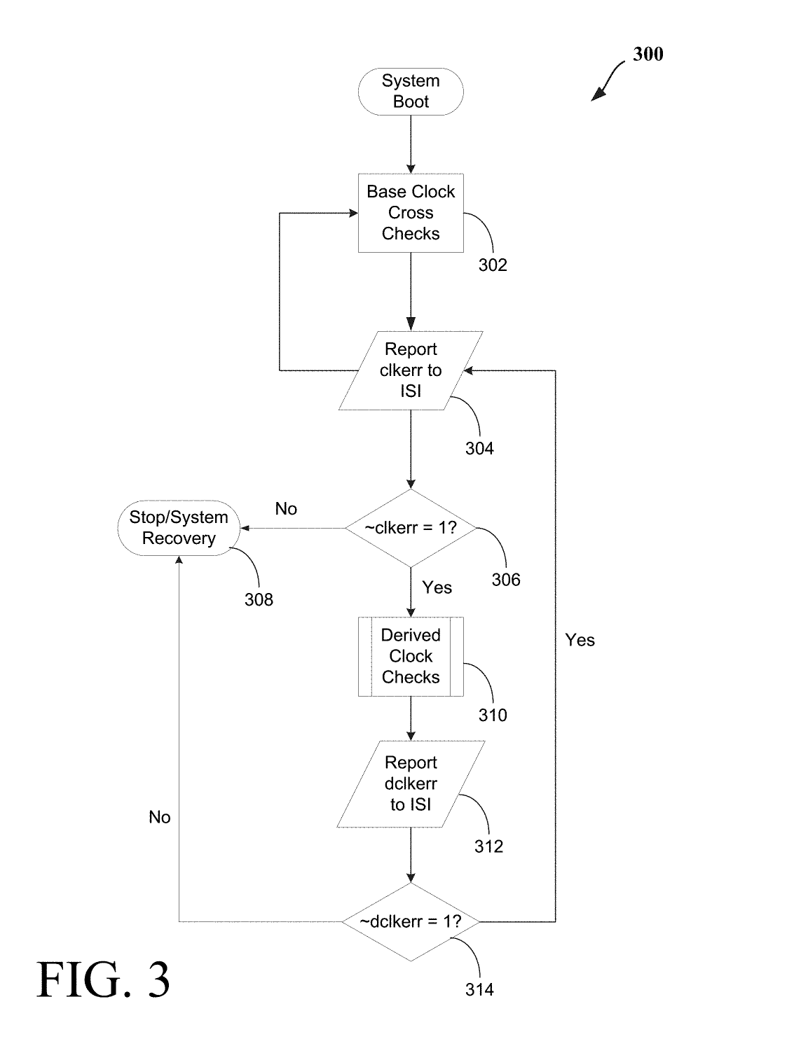

FIG. 3 illustrates a flow diagram of a method 300 to monitor errors for a functional safety clocking framework, according to an embodiment. One or more operations of FIG. 3 may be performed by logic discussed herein with reference to other figures (such as logic 101/102/108/110/etc.).

Referring to FIGS. 1-3, after system boot, operation 302 performs cross checks on base clock(s) (e.g., by logic 110 and/or 113). Operation 304 reports any clock errors to the Integrated Safety Island (ISI) (e.g., logic 113 reports errors to logic 101). Operation 306 determines whether the reported clock error indicates no error (e.g., a “1” indicates error). If there is an error (e.g., frequency, aging, duty cycle, etc. as discussed with reference to FIG. 1) reported for the base clock(s), operation 308 stops the system and causes initiation of system recovery, e.g., depending on the type and/or severity of the reported error such as discussed with reference to FIG. 1.

If there is no error reported at operation 306, operation 310 performs derived clock checks (e.g., by logic 114). Operation 312 reports any derived clock errors to the ISI (e.g., logic 114 reports errors to logic 101). Operation 314 determines whether the reported clock error indicates no error (e.g., a “1” indicates error). If there is an error (e.g., frequency, aging, duty cycle, etc. as discussed with reference to FIG. 1) reported for the derived clock(s), operation 308 stops the system and causes initiation of system recovery, e.g., depending on the type and/or severity of the reported error such as discussed with reference to FIG. 1. If there is no error reported at operation 314, method 300 resumes with operation 304.

In an embodiment, the following clock monitoring criteria may be used:

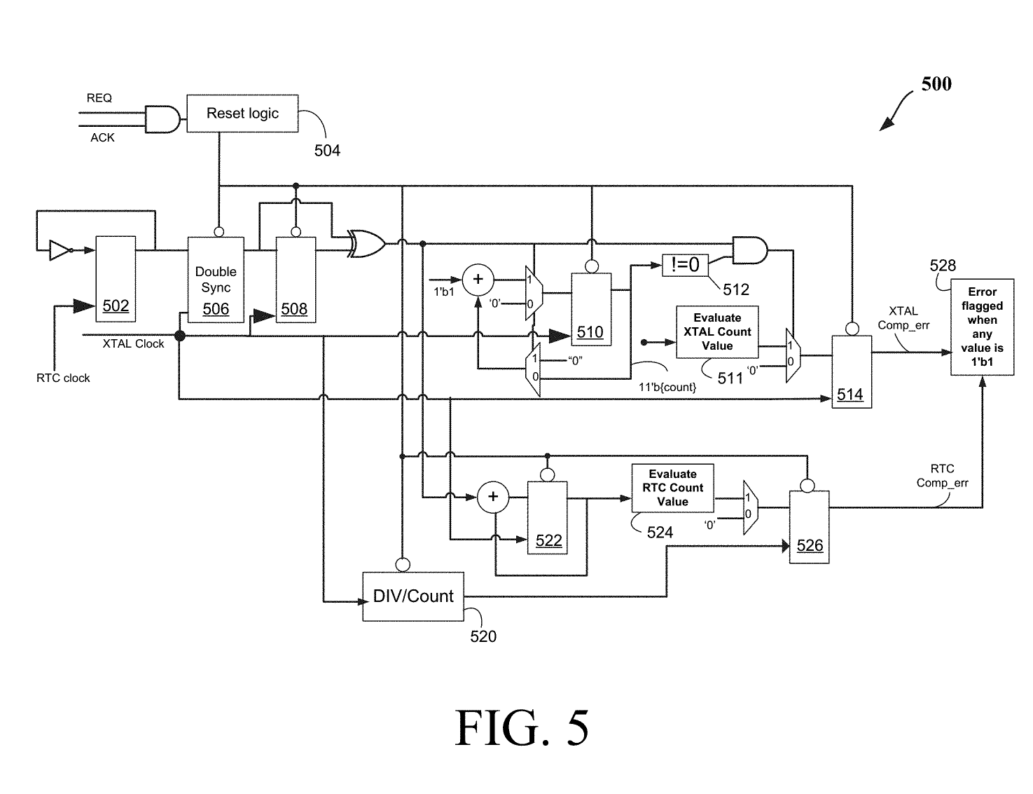

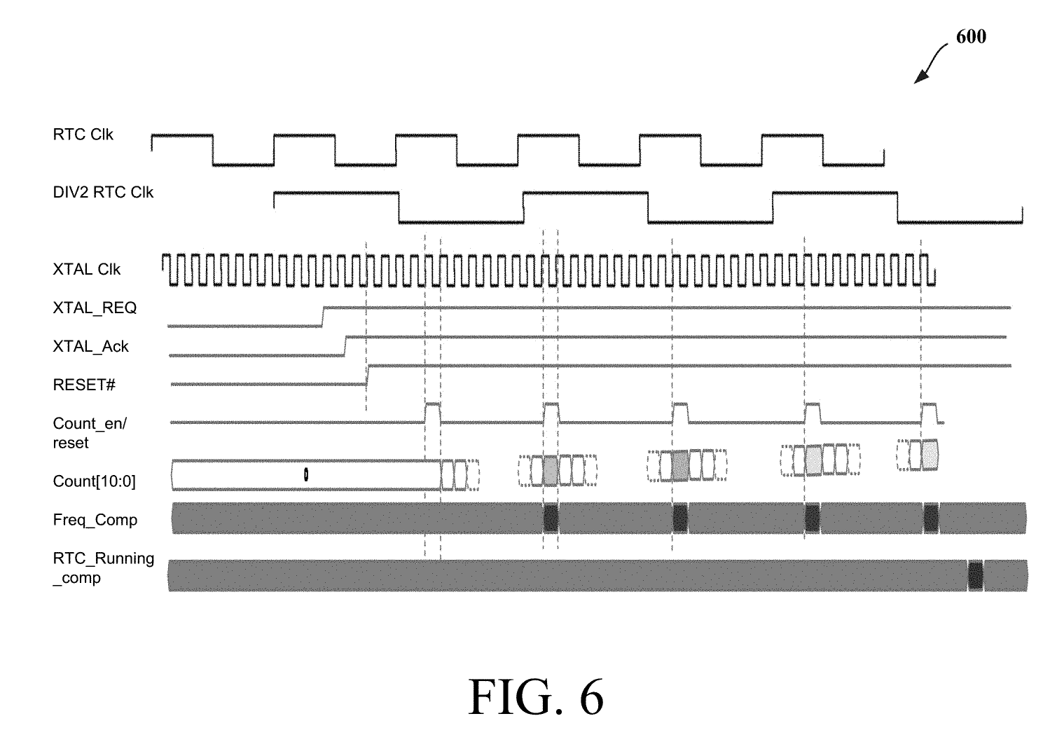

(1) For Safe Clock: cross-check each base clock with respect to each other whether the clock is running or not and flag any errors (FIGS. 5 and 6 illustrate one of the possible implementations of self/cross checking of base clocks and its timing diagram, respectively, according to an embodiment);

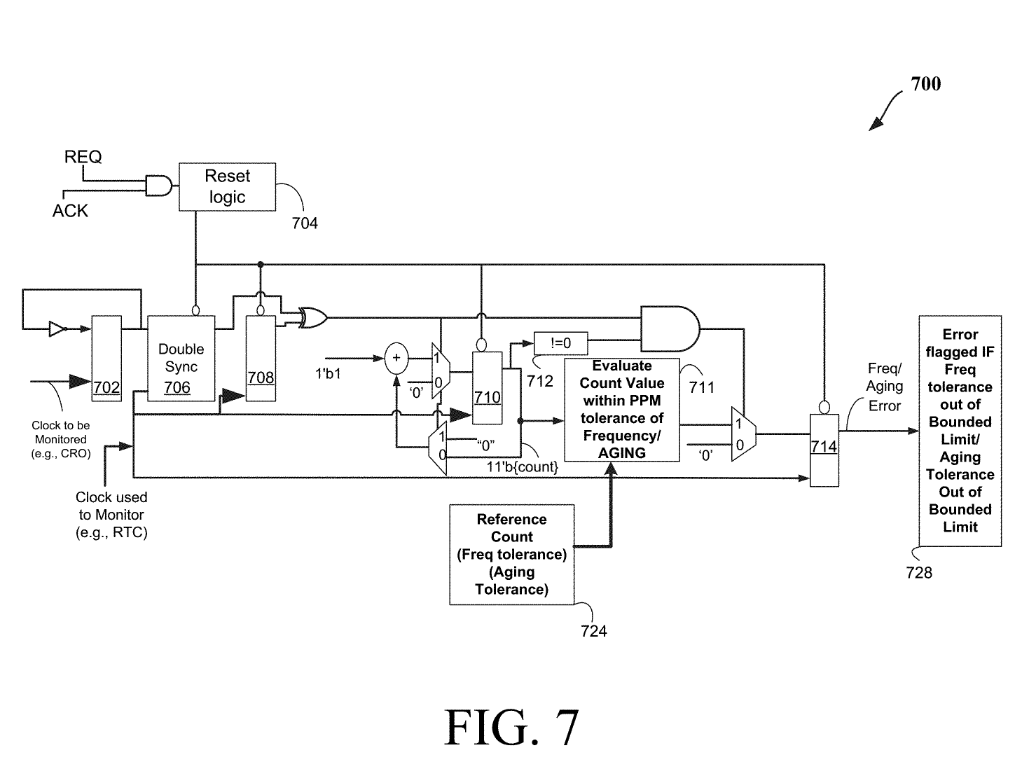

(2) Frequency Error: measure frequency tolerance against reference clock (FIG. 7 shows a block diagram of circuitry to monitor frequency and aging tolerance limits, according to an embodiment; for example, where the monitored clock is a CRO clock which is monitored with respect to RTC clocks, e.g., CRO running @ 200 MHz clock and its frequency calibration code is 6104 (which corresponds to binary code in decimal form) and current error tolerance bounded error is 196 MHz (code: 5981)-204 MHz (code: 6225) (20000 ppm);

(3) Aging: over time aging effects cause frequency variations. As discussed herein, aging “bound” corresponds to a threshold value or limit at which point the system may cease or fail beyond the limit of frequency variation, and as long as the system is within the aging bound, it will function. Even if the codes fall within aging bounds, monotonic movement (i.e., varying in such a way that it either never decreases or never increases) can indicate that circuit is degrading; hence, an embodiment logs golden/standard values from manufacturing stage and delta for aging drift (which can be compared against stored golden values, e.g., per the graph shown in FIG. 4, which shows sample upper and lower bounds (e.g., 15,000 ppm or 20,000 ppm) to determine aging bounds for identification of catastrophic failure potential); and

(4) Duty Cycle Measurement: as discussed herein, duty cycle generally refers to a percentage of time a reference signal is high vs. the total time the reference signal is active. Duty cycle logic (e.g., logic 110) measures clock cycles during high and low time of the reference clock and registers these measurements as high count and low count. Later, flag errors based on the bounded high count/low count set by duty cycle tolerance. For example, if the monitored clock is ten-fold slower than the reference clock, then monitor circuit generates High Count=5 and Low count=5. Comparison logic checks whether High or Low count are within tolerance limits. Flags are generated if the comparison indicates exceeding the count tolerance limits. FIG. 7 can be used for high count and similar circuit for low count. Count enable generated within monitor circuit to enable low/high count monitors.

FIG. 5 illustrates a circuit diagram 500 for base clock domain cross/self-checking, according to an embodiment. In an embodiment, logic 112 and/or 113 of FIG. 1 include the circuit of FIG. 5. FIG. 5 shows that XTAL clock and RTC clock can be cross checked. FIG. 6 illustrates a timing diagram 600 for the base clock cross/self-checking of FIG. 5, according to an embodiment. In the figures, REQ refers to Request and ACK refers to Acknowledgement, which could be used to enabling the logic operation, e.g., when clock is active/available, the detection/checking is performed.

Referring to FIG. 5, logic 502 is used to divide the RTC clock, so that it becomes possible to increase the dynamic range (e.g., to obtain more count value or resolution). Logic 504 can be used to perform a reset of logic 506 based on REQ and ACK signals (that are logically combined via an AND gate). Logic 506 and 508 are used for synchronizing count in RTC clock domain. Logic 514 and 526 is used for synchronization of count in the XTAL clock domain. Logic 510 and 522 is part of digital added and used for counting. Logic 511 and 524 perform comparison operations to evaluate count values. Both logic 511 and 512 are used for cross checking. And, logic 512 is used to generate error based on its comparison operation. Logic 520 is used as a divider for the count value. Logic 510, 514, 522, and 526 part of comparison logic. Logic 528 flags error when the cross checking of the XTAL and RTC clocks fails.

Referring to FIG. 6, RTC clock divined is by 2 which is sampled by XTAL clock. Count is generated for every positive cycle and reset in every negative cycle, or vice versa. Count [10:0] refers to count values. Freq_Comp or RTC_Comp refer to running state-machine count values, which may also be used to control the states of cross check detections.

FIG. 7 illustrates a circuit diagram 700 for applying frequency and aging tolerance limits, according to an embodiment. Circuit 700 monitors a CRO clock with respect to an RTC clock. For example, if the monitored clock is ten-fold slower than the reference clock, then monitor circuit generates High Count=5 and Low count=5. Comparison logic checks whether High or Low count are within tolerance limits.

Referring to FIG. 7, flags are generated (at logic 728) if the comparison indicates exceeding the count tolerance limits. Logic 702 is used to divide the monitored clock (e.g., CRO clock), so that it becomes possible to increase the dynamic range (e.g., to obtain more count value or resolution). Logic 704 can be used to perform a reset of logic 706, 708, 710, 714 based on REQ and ACK signals (that are logically combined via an AND gate). Logic 706 and 708 are used for synchronizing count in CRO clock domain. Logic 710 is used for counting (Digital Counter). Logic 711 and 724 perform comparison operations to evaluate count values. Both logic 711 and 712 are used for cross checking. And, logic 712 is used to generate error based on its comparison operation. Logic 714 performs comparisons. Hence, the circuit of FIG. 7 can be used for high count and a similar circuit for low count. And, a count enable signal generated within monitor circuit can enable low/high count monitoring.

Furthermore, some implementations may be used at platform level, which can only be applied by imposing hardware component intelligence on the platform. However, platform level solutions have limited accessibility of generated clocks at platform level and these can be expensive solutions in terms of adding BOM cost. Also, chip level designers may attempt to meet clocking performance for product life cycle through validation. However, system designer and SOC designer would have to spend a significant amount of time to validate systems under such complex environments. And these validations may rely on reliability simulations which have dependency of how accurate the provided process modeling is. But no such validation process may be robust enough to meet the product life cycle requirements.

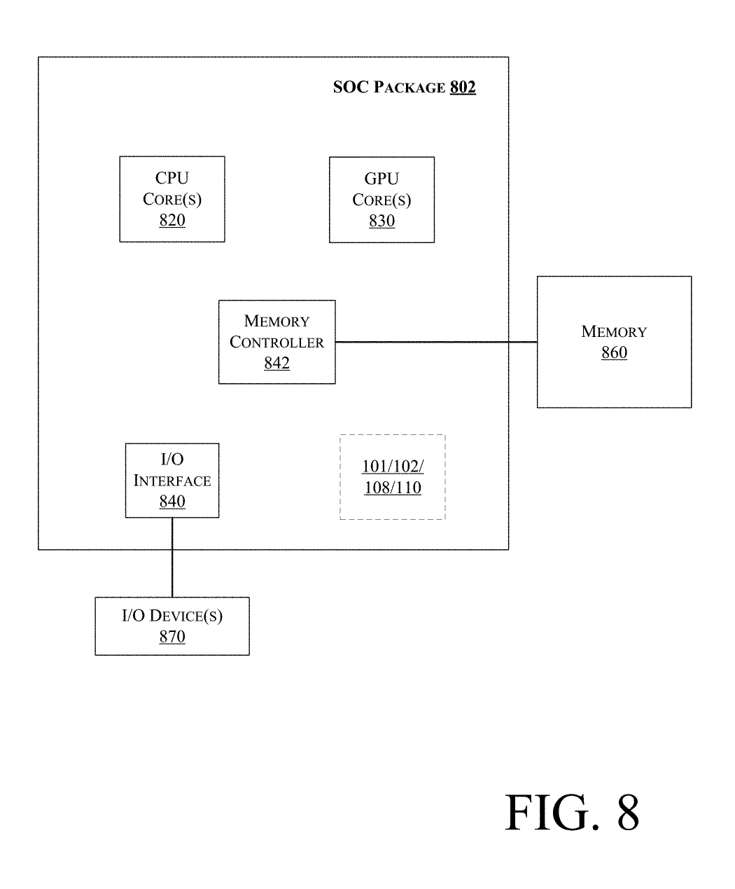

FIG. 8 illustrates a block diagram of an SOC package in accordance with an embodiment. As illustrated in FIG. 8, SOC 802 includes one or more Central Processing Unit (CPU) cores 820, one or more Graphics Processor Unit (GPU) cores 830, an Input/Output (I/O) interface 840, and a memory controller 842. Various components of the SOC package 802 may be coupled to an interconnect or bus such as discussed herein with reference to the other figures. Also, the SOC package 802 may include more or less components, such as those discussed herein with reference to the other figures. Further, each component of the SOC package 820 may include one or more other components, e.g., as discussed with reference to the other figures herein. In one embodiment, SOC package 802 (and its components) is provided on one or more Integrated Circuit (IC) die, e.g., which are packaged into a single semiconductor device.

As illustrated in FIG. 8, SOC package 802 is coupled to a memory 860 via the memory controller 842. In an embodiment, the memory 860 (or a portion of it) can be integrated on the SOC package 802.

The I/O interface 840 may be coupled to one or more I/O devices 870, e.g., via an interconnect and/or bus such as discussed herein with reference to other figures. I/O device(s) 870 may include one or more of a keyboard, a mouse, a touchpad, a display, an image/video capture device (such as a camera or camcorder/video recorder), a touch screen, a speaker, or the like.

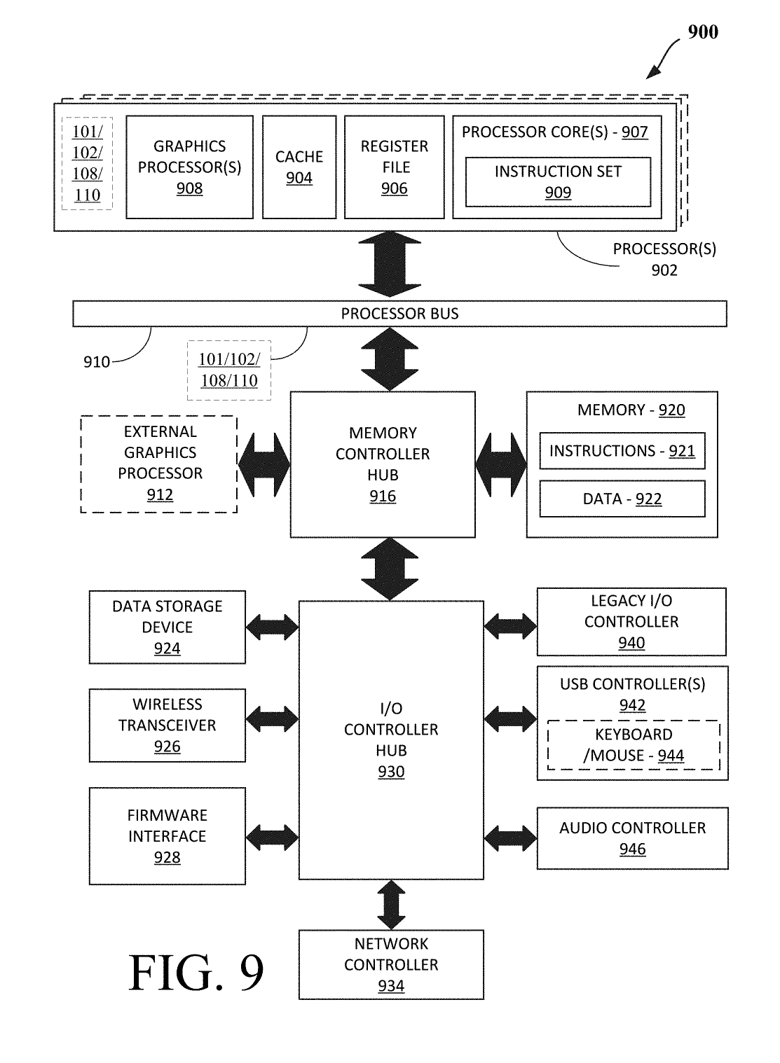

FIG. 9 is a block diagram of a processing system 900, according to an embodiment. In various embodiments the system 900 includes one or more processors 902 and one or more graphics processors 908, and may be a single processor desktop system, a multiprocessor workstation system, or a server system having a large number of processors 902 or processor cores 907. In on embodiment, the system 900 is a processing platform incorporated within a system-on-a-chip (SoC or SOC) integrated circuit for use in mobile, handheld, or embedded devices.

An embodiment of system 900 can include, or be incorporated within a server-based gaming platform, a game console, including a game and media console, a mobile gaming console, a handheld game console, or an online game console. In some embodiments system 900 is a mobile phone, smart phone, tablet computing device or mobile Internet device. Data processing system 900 can also include, couple with, or be integrated within a wearable device, such as a smart watch wearable device, smart eyewear device, augmented reality device, or virtual reality device. In some embodiments, data processing system 900 is a television or set top box device having one or more processors 902 and a graphical interface generated by one or more graphics processors 908.

In some embodiments, the one or more processors 902 each include one or more processor cores 907 to process instructions which, when executed, perform operations for system and user software. In some embodiments, each of the one or more processor cores 907 is configured to process a specific instruction set 909. In some embodiments, instruction set 909 may facilitate Complex Instruction Set Computing (CISC), Reduced Instruction Set Computing (RISC), or computing via a Very Long Instruction Word (VLIW). Multiple processor cores 907 may each process a different instruction set 909, which may include instructions to facilitate the emulation of other instruction sets. Processor core 907 may also include other processing devices, such a Digital Signal Processor (DSP).

In some embodiments, the processor 902 includes cache memory 904. Depending on the architecture, the processor 902 can have a single internal cache or multiple levels of internal cache. In some embodiments, the cache memory is shared among various components of the processor 902. In some embodiments, the processor 902 also uses an external cache (e.g., a Level-3 (L3) cache or Last Level Cache (LLC)) (not shown), which may be shared among processor cores 907 using known cache coherency techniques. A register file 906 is additionally included in processor 902 which may include different types of registers for storing different types of data (e.g., integer registers, floating point registers, status registers, and an instruction pointer register). Some registers may be general-purpose registers, while other registers may be specific to the design of the processor 902.

In some embodiments, processor 902 is coupled to a processor bus 910 to transmit communication signals such as address, data, or control signals between processor 902 and other components in system 900. In one embodiment the system 900 uses an exemplary ‘hub’ system architecture, including a memory controller hub 916 and an Input Output (I/O) controller hub 930. A memory controller hub 916 facilitates communication between a memory device and other components of system 900, while an I/O Controller Hub (ICH) 930 provides connections to I/O devices via a local I/O bus. In one embodiment, the logic of the memory controller hub 916 is integrated within the processor.

Memory device 920 can be a dynamic random access memory (DRAM) device, a static random access memory (SRAM) device, flash memory device, phase-change memory device, or some other memory device having suitable performance to serve as process memory. In one embodiment the memory device 920 can operate as system memory for the system 900, to store data 922 and instructions 921 for use when the one or more processors 902 executes an application or process. Memory controller hub 916 also couples with an optional external graphics processor 912, which may communicate with the one or more graphics processors 908 in processors 902 to perform graphics and media operations.

In some embodiments, ICH 930 enables peripherals to connect to memory device 920 and processor 902 via a high-speed I/O bus. The I/O peripherals include, but are not limited to, an audio controller 946, a firmware interface 928, a wireless transceiver 926 (e.g., Wi-Fi, Bluetooth), a data storage device 924 (e.g., hard disk drive, flash memory, etc.), and a legacy I/O controller 940 for coupling legacy (e.g., Personal System 2 (PS/2)) devices to the system. One or more Universal Serial Bus (USB) controllers 942 connect input devices, such as keyboard and mouse 944 combinations. A network controller 934 may also couple to ICH 930. In some embodiments, a high-performance network controller (not shown) couples to processor bus 910. It will be appreciated that the system 900 shown is exemplary and not limiting, as other types of data processing systems that are differently configured may also be used. For example, the I/O controller hub 930 may be integrated within the one or more processor 902, or the memory controller hub 916 and I/O controller hub 930 may be integrated into a discreet external graphics processor, such as the external graphics processor 912.

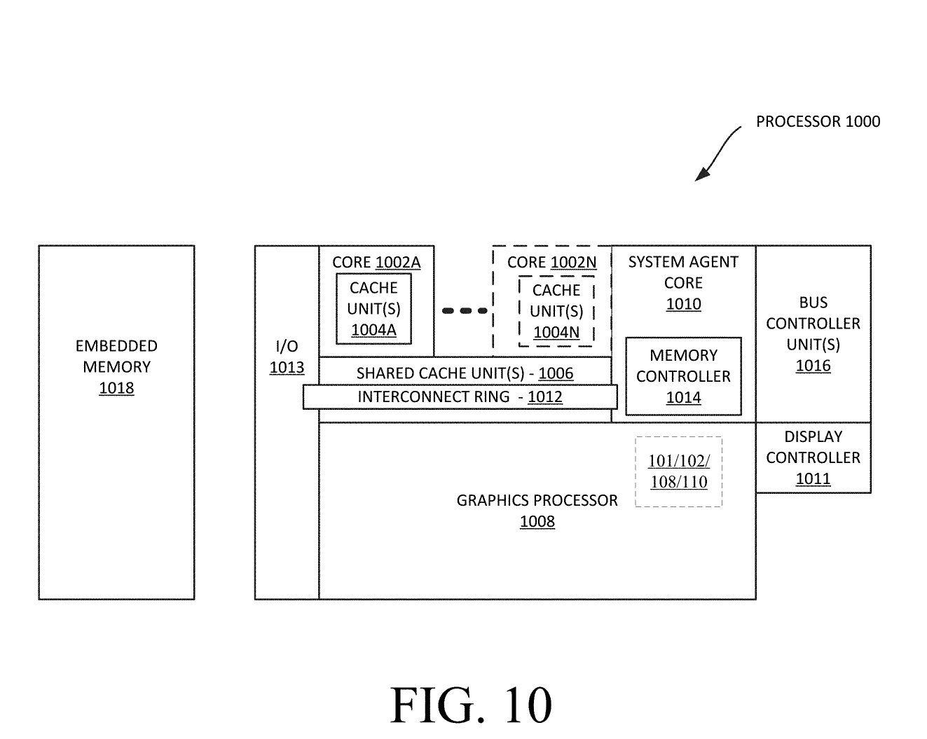

FIG. 10 is a block diagram of an embodiment of a processor 1000 having one or more processor cores 1002A to 1002N, an integrated memory controller 1014, and an integrated graphics processor 1008. Those elements of FIG. 10 having the same reference numbers (or names) as the elements of any other figure herein can operate or function in any manner similar to that described elsewhere herein, but are not limited to such. Processor 1000 can include additional cores up to and including additional core 1002N represented by the dashed lined boxes. Each of processor cores 1002A to 1002N includes one or more internal cache units 1004A to 1004N. In some embodiments each processor core also has access to one or more shared cached units 1006.

The internal cache units 1004A to 1004N and shared cache units 1006 represent a cache memory hierarchy within the processor 1000. The cache memory hierarchy may include at least one level of instruction and data cache within each processor core and one or more levels of shared mid-level cache, such as a Level 2 (L2), Level 3 (L3), Level 4 (L4), or other levels of cache, where the highest level of cache before external memory is classified as the LLC. In some embodiments, cache coherency logic maintains coherency between the various cache units 1006 and 1004A to 1004N.

In some embodiments, processor 1000 may also include a set of one or more bus controller units 1016 and a system agent core 1010. The one or more bus controller units 1016 manage a set of peripheral buses, such as one or more Peripheral Component Interconnect buses (e.g., PCI, PCI Express). System agent core 1010 provides management functionality for the various processor components. In some embodiments, system agent core 1010 includes one or more integrated memory controllers 1014 to manage access to various external memory devices (not shown).

In some embodiments, one or more of the processor cores 1002A to 1002N include support for simultaneous multi-threading. In such embodiment, the system agent core 1010 includes components for coordinating and operating cores 1002A to 1002N during multi-threaded processing. System agent core 1010 may additionally include a power control unit (PCU), which includes logic and components to regulate the power state of processor cores 1002A to 1002N and graphics processor 1008.

In some embodiments, processor 1000 additionally includes graphics processor 1008 to execute graphics processing operations. In some embodiments, the graphics processor 1008 couples with the set of shared cache units 1006, and the system agent core 1010, including the one or more integrated memory controllers 1014. In some embodiments, a display controller 1011 is coupled with the graphics processor 1008 to drive graphics processor output to one or more coupled displays. In some embodiments, display controller 1011 may be a separate module coupled with the graphics processor via at least one interconnect, or may be integrated within the graphics processor 1008 or system agent core 1010.

In some embodiments, a ring based interconnect unit 1012 is used to couple the internal components of the processor 1000. However, an alternative interconnect unit may be used, such as a point-to-point interconnect, a switched interconnect, or other techniques, including techniques well known in the art. In some embodiments, graphics processor 1008 couples with the ring interconnect 1012 via an I/O link 1013.

The exemplary I/O link 1013 represents at least one of multiple varieties of I/O interconnects, including an on package I/O interconnect which facilitates communication between various processor components and a high-performance embedded memory module 1018, such as an eDRAM (or embedded DRAM) module. In some embodiments, each of the processor cores 1002 to 1002N and graphics processor 1008 use embedded memory modules 1018 as a shared Last Level Cache.

In some embodiments, processor cores 1002A to 1002N are homogenous cores executing the same instruction set architecture. In another embodiment, processor cores 1002A to 1002N are heterogeneous in terms of instruction set architecture (ISA), where one or more of processor cores 1002A to 1002N execute a first instruction set, while at least one of the other cores executes a subset of the first instruction set or a different instruction set. In one embodiment processor cores 1002A to 1002N are heterogeneous in terms of microarchitecture, where one or more cores having a relatively higher power consumption couple with one or more power cores having a lower power consumption. Additionally, processor 1000 can be implemented on one or more chips or as an SoC integrated circuit having the illustrated components, in addition to other components.

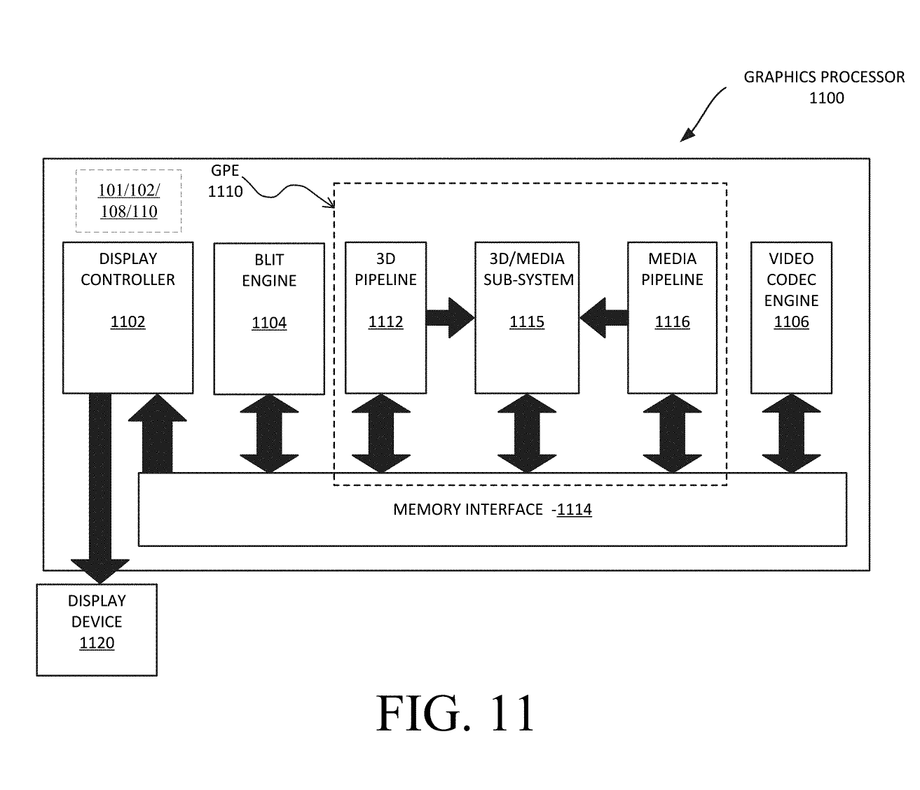

FIG. 11 is a block diagram of a graphics processor 1100, which may be a discrete graphics processing unit, or may be a graphics processor integrated with a plurality of processing cores. In some embodiments, the graphics processor communicates via a memory mapped I/O interface to registers on the graphics processor and with commands placed into the processor memory. In some embodiments, graphics processor 1100 includes a memory interface 1114 to access memory. Memory interface 1114 can be an interface to local memory, one or more internal caches, one or more shared external caches, and/or to system memory.

In some embodiments, graphics processor 1100 also includes a display controller 1102 to drive display output data to a display device 1120. Display controller 1102 includes hardware for one or more overlay planes for the display and composition of multiple layers of video or user interface elements. In some embodiments, graphics processor 1100 includes a video codec engine 1106 to encode, decode, or transcode media to, from, or between one or more media encoding formats, including, but not limited to Moving Picture Experts Group (MPEG) formats such as MPEG-2, Advanced Video Coding (AVC) formats such as H.264/MPEG-4 AVC, as well as the Society of Motion Picture & Television Engineers (SMPTE) 421M/VC-1, and Joint Photographic Experts Group (JPEG) formats such as JPEG, and Motion JPEG (MJPEG) formats.

In some embodiments, graphics processor 1100 includes a block image transfer (BLIT) engine 1104 to perform two-dimensional (2D) rasterizer operations including, for example, bit-boundary block transfers. However, in one embodiment, 11D graphics operations are performed using one or more components of graphics processing engine (GPE) 1110. In some embodiments, graphics processing engine 1110 is a compute engine for performing graphics operations, including three-dimensional (3D) graphics operations and media operations.

In some embodiments, GPE 1110 includes a 3D pipeline 1112 for performing 3D operations, such as rendering three-dimensional images and scenes using processing functions that act upon 3D primitive shapes (e.g., rectangle, triangle, etc.). The 3D pipeline 1112 includes programmable and fixed function elements that perform various tasks within the element and/or spawn execution threads to a 3D/Media sub-system 1115. While 3D pipeline 1112 can be used to perform media operations, an embodiment of GPE 1110 also includes a media pipeline 1116 that is specifically used to perform media operations, such as video post-processing and image enhancement.

In some embodiments, media pipeline 1116 includes fixed function or programmable logic units to perform one or more specialized media operations, such as video decode acceleration, video de-interlacing, and video encode acceleration in place of, or on behalf of video codec engine 1106. In some embodiments, media pipeline 1116 additionally includes a thread spawning unit to spawn threads for execution on 3D/Media sub-system 1115. The spawned threads perform computations for the media operations on one or more graphics execution units included in 3D/Media sub-system 1115.

In some embodiments, 3D/Media subsystem 1115 includes logic for executing threads spawned by 3D pipeline 1112 and media pipeline 1116. In one embodiment, the pipelines send thread execution requests to 3D/Media subsystem 1115, which includes thread dispatch logic for arbitrating and dispatching the various requests to available thread execution resources. The execution resources include an array of graphics execution units to process the 3D and media threads. In some embodiments, 3D/Media subsystem 1115 includes one or more internal caches for thread instructions and data. In some embodiments, the subsystem also includes shared memory, including registers and addressable memory, to share data between threads and to store output data.

The following examples pertain to further embodiments. Example 1 includes an apparatus comprising: clock monitoring logic circuitry to monitor a plurality of clock signals; safety island logic circuitry to receive an error status signal from the clock monitoring logic circuitry based at least in part on a determination of whether an error exists for at least one of the plurality of clock signals; and safety logic circuitry to receive an interrupt signal from the safety island logic circuitry in response to a determination that the error status signal indicates existence of an error for at least one of the plurality of clock signals, wherein the plurality of clock signals comprises one or more of: a base clock signal or a derived clock signal, wherein the derived clock signal is to be generated based on the base clock signal. Example 2 includes the apparatus of example 1, wherein the clock monitoring logic circuitry is to determine whether the error exists based on a cross check of two of the plurality of clock signals. Example 3 includes the apparatus of example 1, wherein the clock monitoring logic circuitry is to determine whether the error exists for the base clock signal before the derived clock signal. Example 4 includes the apparatus of example 1, wherein the error is one or more of: an frequency error, an aging error, a duty cycle error, a clock lock error, and a phase error. Example 5 includes the apparatus of example 4, wherein the clock monitoring logic circuitry is to determine existence of the aging error based on monotonic movement of one or more of the plurality of clock signals. Example 6 includes the apparatus of example 1, wherein the error status signal is to indicate status of the error based on at least two bits of data. Example 7 includes the apparatus of example 1, wherein error status signal is to indicate absence any error for the plurality of clock signals. Example 8 includes the apparatus of example 1, comprising error handling logic circuitry to generate the interrupt signal. Example 9 includes the apparatus of example 8, wherein the safety island logic circuitry comprises the error handling logic circuitry. Example 10 includes the apparatus of example 1, wherein a System On Chip (SOC) device comprises the clock monitory logic circuitry and the safety island logic circuitry, wherein the safety logic circuitry resides outside of the SOC device, wherein the safety logic circuitry is coupled to the safety island logic circuitry via an input/output bus or a system bus. Example 11 includes the apparatus of example 1, wherein a System On Chip (SOC) device comprises the clock monitory logic circuitry, the safety island logic circuitry, and the safety logic circuitry. Example 12 includes the apparatus of example 1, comprising an input/output bus or a system bus to communicate the error signal. Example 13 includes the apparatus of example 1, wherein the clock monitoring logic circuity is to generate the error status signal in response to the determination by the clock monitoring logic circuitry of whether an error exists for at least one of the plurality of clock signals. Example 14 includes the apparatus of example 1, comprising logic circuitry to generate the plurality of clock signals. Example 15 includes the apparatus of example 1, wherein the clock monitoring logic comprises one or more state machines to check the plurality of clock signals. Example 16 includes the apparatus of example 1, wherein an Internet of Things (IoT) device or vehicle comprises one or more of: the clock monitory logic circuitry, the safety island logic circuitry, the safety logic circuitry, and memory. Example 17 includes the apparatus of example 1, wherein a processor, having one or more processor cores, comprises one or more of: the clock monitory logic circuitry, the safety island logic circuitry, the safety logic circuitry, and memory. Example 18 includes the apparatus of example 1, wherein a single integrated device comprises one or more of: a processor, the clock monitory logic circuitry, the safety island logic circuitry, the safety logic circuitry, and memory.

Example 19 includes one or more computer-readable medium comprising one or more instructions that when executed on at least one processor configure the at least one processor to perform one or more operations to cause: clock monitoring logic circuitry to monitor a plurality of clock signals; safety island logic circuitry to receive an error status signal from the clock monitoring logic circuitry based at least in part on a determination of whether an error exists for at least one of the plurality of clock signals; and safety logic circuitry to receive an interrupt signal from the safety island logic circuitry in response to a determination that the error status signal indicates existence of an error for at least one of the plurality of clock signals, wherein the plurality of clock signals comprises one or more of: a base clock signal or a derived clock signal, wherein the derived clock signal is to be generated based on the base clock signal. Example 20 includes the one or more computer-readable medium of example 19, further comprising one or more instructions that when executed on the at least one processor configure the at least one processor to perform one or more operations to cause the clock monitoring logic circuitry to determine whether the error exists based on a cross check of two of the plurality of clock signals. Example 21 includes the one or more computer-readable medium of example 19, further comprising one or more instructions that when executed on the at least one processor configure the at least one processor to perform one or more operations to cause the clock monitoring logic circuitry to determine whether the error exists for the base clock signal before the derived clock signal. Example 22 includes the one or more computer-readable medium of example 19, wherein the error is one or more of: an frequency error, an aging error, a duty cycle error, a clock lock error, and a phase error. Example 23 includes the one or more computer-readable medium of example 22, further comprising one or more instructions that when executed on the at least one processor configure the at least one processor to perform one or more operations to cause the clock monitoring logic circuitry to determine existence of the aging error based on monotonic movement of one or more of the plurality of clock signals.

Example 24 includes an apparatus comprising means to perform a method as set forth in any preceding example.

Example 25 comprises machine-readable storage including machine-readable instructions, when executed, to implement a method or realize an apparatus as set forth in any preceding example.

In various embodiments, the operations discussed herein, e.g., with reference to FIG. 1 et seq., may be implemented as hardware (e.g., logic circuitry or more generally circuitry or circuit), software, firmware, or combinations thereof, which may be provided as a computer program product, e.g., including a tangible (e.g., non-transitory) machine-readable or computer-readable medium having stored thereon instructions (or software procedures) used to program a computer to perform a process discussed herein. The machine-readable medium may include a storage device such as those discussed with respect to FIG. 1 et seq.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
clock monitoring logic circuitry to monitor a plurality of clock signals;
safety island logic circuitry to receive an error status signal from the clock monitoring logic circuitry based at least in part on a determination of whether an error exists for at least one of the plurality of clock signals; and
safety logic circuitry to receive an interrupt signal from the safety island logic circuitry in response to a determination that the error status signal indicates existence of an error for at least one of the plurality of clock signals, wherein the plurality of clock signals comprises one or more of: a base clock signal or a derived clock signal, wherein the derived clock signal is to be generated based on the base clock signal.

2. The apparatus of claim 1, wherein the clock monitoring logic circuitry is to determine whether the error exists based on a cross check of two of the plurality of clock signals.

3. The apparatus of claim 1, wherein the clock monitoring logic circuitry is to determine whether the error exists for the base clock signal before the derived clock signal.

4. The apparatus of claim 1, wherein the error is one or more of: an frequency error, an aging error, a duty cycle error, a clock lock error, and a phase error.

5. The apparatus of claim 4, wherein the clock monitoring logic circuitry is to determine existence of the aging error based on monotonic movement of one or more of the plurality of clock signals.

6. The apparatus of claim 1, wherein the error status signal is to indicate status of the error based on at least two bits of data.

7. The apparatus of claim 1, wherein error status signal is to indicate absence any error for the plurality of clock signals.

8. The apparatus of claim 1, comprising error handling logic circuitry to generate the interrupt signal.

9. The apparatus of claim 8, wherein the safety island logic circuitry comprises the error handling logic circuitry.

10. The apparatus of claim 1, wherein a System On Chip (SOC) device comprises the clock monitory logic circuitry and the safety island logic circuitry, wherein the safety logic circuitry resides outside of the SOC device, wherein the safety logic circuitry is coupled to the safety island logic circuitry via an input/output bus or a system bus.

11. The apparatus of claim 1, wherein a System On Chip (SOC) device comprises the clock monitory logic circuitry, the safety island logic circuitry, and the safety logic circuitry.

12. The apparatus of claim 1, comprising an input/output bus or a system bus to communicate the error signal.

13. The apparatus of claim 1, wherein the clock monitoring logic circuity is to generate the error status signal in response to the determination by the clock monitoring logic circuitry of whether an error exists for at least one of the plurality of clock signals.

14. The apparatus of claim 1, comprising logic circuitry to generate the plurality of clock signals.

15. The apparatus of claim 1, wherein the clock monitoring logic comprises one or more state machines to check the plurality of clock signals.

16. The apparatus of claim 1, wherein an Internet of Things (IoT) device or vehicle comprises one or more of: the clock monitory logic circuitry, the safety island logic circuitry, the safety logic circuitry, and memory.

17. The apparatus of claim 1, wherein a processor, having one or more processor cores, comprises one or more of: the clock monitory logic circuitry, the safety island logic circuitry, the safety logic circuitry, and memory.

18. The apparatus of claim 1, wherein a single integrated device comprises one or more of: a processor, the clock monitory logic circuitry, the safety island logic circuitry, the safety logic circuitry, and memory.

19. One or more computer-readable medium comprising one or more instructions that when executed on at least one processor configure the at least one processor to perform one or more operations to cause:
clock monitoring logic circuitry to monitor a plurality of clock signals;
safety island logic circuitry to receive an error status signal from the clock monitoring logic circuitry based at least in part on a determination of whether an error exists for at least one of the plurality of clock signals; and
safety logic circuitry to receive an interrupt signal from the safety island logic circuitry in response to a determination that the error status signal indicates existence of an error for at least one of the plurality of clock signals, wherein the plurality of clock signals comprises one or more of: a base clock signal or a derived clock signal, wherein the derived clock signal is to be generated based on the base clock signal.

20. The one or more computer-readable medium of claim 19, further comprising one or more instructions that when executed on the at least one processor configure the at least one processor to perform one or more operations to cause the clock monitoring logic circuitry to determine whether the error exists based on a cross check of two of the plurality of clock signals.

21. The one or more computer-readable medium of claim 19, further comprising one or more instructions that when executed on the at least one processor configure the at least one processor to perform one or more operations to cause the clock monitoring logic circuitry to determine whether the error exists for the base clock signal before the derived clock signal.

22. The one or more computer-readable medium of claim 19, wherein the error is one or more of: an frequency error, an aging error, a duty cycle error, a clock lock error, and a phase error.

23. The one or more computer-readable medium of claim 22, further comprising one or more instructions that when executed on the at least one processor configure the at least one processor to perform one or more operations to cause the clock monitoring logic circuitry to determine existence of the aging error based on monotonic movement of one or more of the plurality of clock signals.
